(19) United States
(12) Patent Application Publication
(10) Pub. No.: US 2015/0311090 A1
(43) Pub. Date: Oct. 29, 2015

(54) METHOD OF MANUFACTURING A SEMICONDUCTOR DEVICE

(71) Applicant: KABUSHIKI KAISHA TOSHIBA, Tokyo (JP)

(72) Inventors: Tatsunori ISOGAI, Yokkaichi Mie (JP); Tomonori AOYAMA, Yokkaichi Mie (JP)

(21) Appl. No.: 14/636,178

(22) Filed: Mar. 3, 2015

(30) Foreign Application Priority Data
Apr. 28, 2014 (JP) 2014-092842

(51) Int. Cl. H01L 21/3115; H01L 21/324; H01L 49/02

(52) U.S. Cl. CPC H01L 21/31155; H01L 28/40; H01L 21/324

(57) ABSTRACT

A method for manufacturing a semiconductor device includes forming a first layer above a semiconductor substrate, implanting in a surface of the first layer, at least one kind of ions of an element contained in the first layer, and applying microwave to the first layer in which at least one kind of the ions are implanted.

### CROSS-REFERENCE TO RELATED APPLICATION

This application is based upon and claims the benefit of priority from Japanese Patent Application No. 2014-092842, filed Apr. 28, 2014, the entire contents of which are incorporated herein by reference.

### FIELD

Embodiments described herein relate generally to a manufacturing method of a semiconductor device.

### BACKGROUND

A thin film, such as a metal thin film, insulating thin film, and a semiconductor thin film, may not have the desired composition, because an element of the composition may be lacking in a portion of the thin film. According to the related art, an ion can be implanted in the portion of the thin film so as to supplement the lacking element.

When the ion is implanted, however, a defect may be developed in the thin film. As such a defect may negatively affect crystallization and conductivity of the thin film, it would be preferable to repair the defect.

### DESCRIPTION OF THE DRAWINGS

FIGS. 1-13 each are a cross-sectional view illustrating an example of a semiconductor device according to an embodiment during a manufacturing process. FIGS. 1-13 each describe a manufacturing step in this order.

### DETAILED DESCRIPTION

In general, according to one embodiment, a method for manufacturing a semiconductor device includes forming a first layer above a semiconductor substrate, implanting in a surface of the first layer, at least one kind of ions of an element contained in the first layer, and applying microwave to the first layer in which at least one kind of the ions are implanted.

Hereinafter, embodiments will be described with reference to the drawings. In addition, the drawings are schematic, and a relationship between a thickness and a plane dimension, a ratio of thickness of each layer, or the like, in the drawings may be different from an actual relationship.

In an embodiment, a method of manufacturing a semiconductor device including an insulating layer, which functions as memory, will be described. The semiconductor device may be a FeRAM (Ferroelectric Random Access Memory), PCRAM (Phase-change Random Access Memory), MRAM (Magnetoresistive Random Access Memory), or the like.

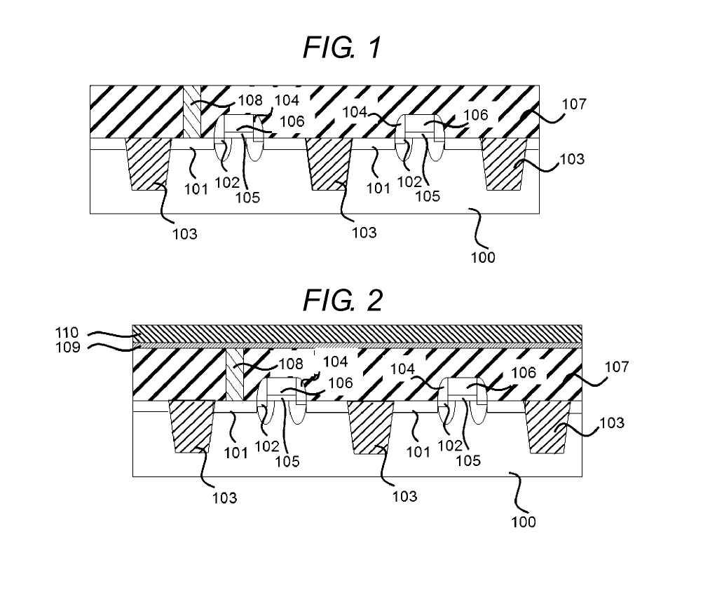

FIG. 1 to FIG. 13 are cross sectional views illustrating an example of a semiconductor device according to the present embodiment during a manufacturing process. As illustrated in FIG. 1, a semiconductor substrate 100 is put in a chamber (not shown). A source or drain portion 101 are formed in at least a part of a surface of the semiconductor substrate 100. A conductive type of the semiconductor substrate 100 is n-type. A conductive type of the source or drain portion 101 is p-type. An extension portion 102 and a STI (Shallow Trench Isolation) 103 are formed in at least a part of the surface of the semiconductor substrate 100.

As the semiconductor substrate 100, for example, it is possible to use a mono crystal substrate, which is one of the mono crystal silicon substrate having a plane direction (100), a mono crystal germanium substrate, a mono crystal silicon germanium substrate, a mono crystal silicon carbide substrate, a mono crystal gallium arsenide substrate, or a silicon-on-insulator (SOI) substrate. Also, as the semiconductor substrate 100, it is possible to use a poly crystal substrate or an amorphous substrate which includes one of the above elements. A gate insulating layer 105 and a gate electrode 106 are provided above the semiconductor substrate 100. A side wall insulating layer 104 is provided on a side surface of the gate insulating layer 105 and the gate electrode 106. The side wall insulating layer 104 is provided above the extension portion 102. As the gate insulating layer 105, for example, it is possible to use a silicon oxide film, a silicon oxynitrate film, or a high-k film. The silicon oxide film is able to be formed using a thermal oxidation method or a plasma oxidation method. The silicon oxynitrate film is able to be formed through plasma processing or by heating the silicon oxide film in the chamber with nitrogen gas. The gate electrode 106 is provided above at least a part of the source or drain portion 101.

A first insulating layer 107 is provided above the semiconductor substrate 100. A first tungsten plug 108 is provided on at least a part of the source or drain portion 101.

As illustrated in FIG. 2, a lower pre-electrode 109 is provided on the first insulating layer 107. A pre-thin film 110 is provided on the lower pre-electrode 109. The pre-thin film 110 is a layer which is processed into a dielectric layer (described below). A thickness of the pre-thin film 110 is about equal to or thicker than 1 nm and equal to or thinner than 200 nm. The lower pre-electrode 109 includes, for example, platinum or iridium oxide. The pre-thin film 110 is an insulating film and includes an oxide of bismuth, lanthanum, or titanium.

An amount of gas fed into the chamber may be insufficient or a glowing speed of each element in the pre-thin film 110 may be different, when the pre-thin film 110 is formed. As a result, the pre-thin film 110 may include a portion in which an aimed element lacks. In other words, a chemical composition of the pre-thin film 110 may not match an aimed chemical composition of the pre-thin film 110.

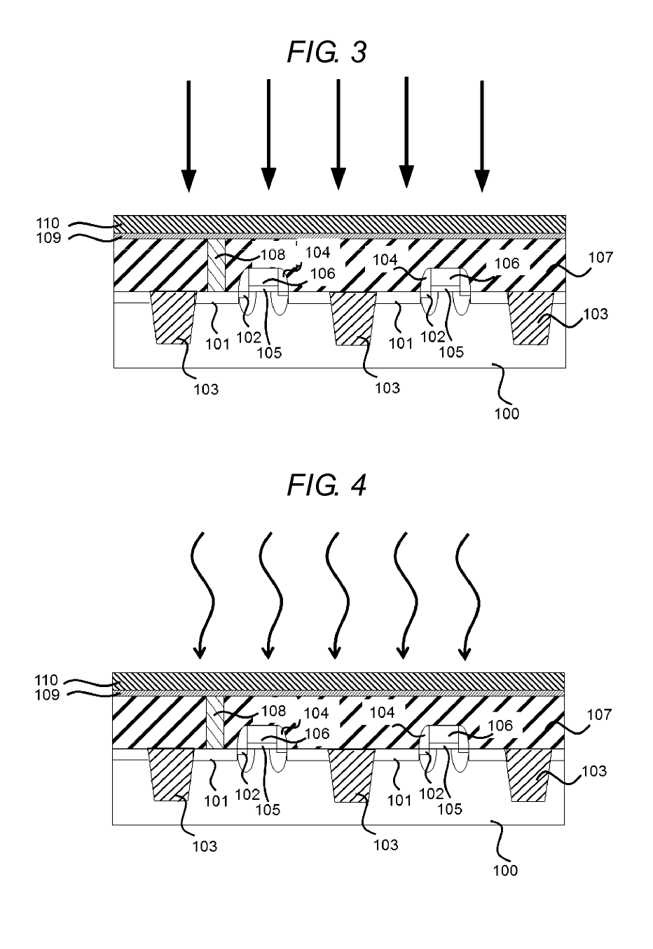

As illustrated in FIG. 3, oxygen ion is implanted in the pre-thin film 110. The thickness of the pre-thin film 110 is about equal to or thicker than 1 nm and equal to or thinner than 200 nm, so a plasma doping method is preferable to effectively implant oxygen in the pre-thin film 110. The implanted pre-thin film 110 includes implanted oxygen ion, which lacks in the portion of the pre-thin film 110. However, when the ion is implanted, the ion impacts the pre-thin film 110a and a defect may be developed in the pre-thin film 110a.

The implantation is carried out in the chamber in which the oxygen gas and a diluent gas for plasma excitation are fed. As the diluent gas, for example, it is possible to use helium gas, neon gas, or argon gas.

During the implantation, a high-frequency radiation, for example, 13.56 MHz radiation, is applied in the chamber for ionizing oxygen. When the high-frequency radiation is applied, a voltage is applied to the semiconductor substrate 100, and as a result the oxygen ion is attracted to the semiconductor substrate 100. Then, the oxygen ion is implanted in the pre-thin film 110.

Acceleration energy of the ion during the implantation is, for example, equal to or greater than 0.5 keV and equal to or smaller than 9.0 keV. A dose amount of the ion is, for example, equal to or greater than 1.0E14 cm10E-2 and is equal to or smaller than 1.0E15 cm10E-2. These amounts are determined so as to prevent the ion from passing through the pre-thin film 110 and detrimentally affecting the semiconductor substrate 100 when the thickness of the pre-thin film 110 is thin.

In this embodiment, the oxygen ion, which lacks in the metal oxide, is implanted. But it is possible to implant any lacking ions. It is possible to implant, for example, nitrogen ion, ion of semiconductor element or metal ion including aluminum ion, silicon ion, germanium ion, cobalt ion, nickel ion, cupper ion, titanium ion, vanadium ion, manganese ion, iron ion, tantalum ion, tungsten ion, and the like. The ion, which lacks in the portion of the pre-thin film 110, is able to be implanted by a beam line implantation method, when the thickness of the pre-thin film 110 is thick, for example equal to or thicker than 20 nm.

The semiconductor substrate may be cleaned after the implantation of the ion.

As illustrated in FIG. 4, micro wave is applied to the pre-thin film 110 and the pre-thin film 110 is heated by the microwave. At this time, a defect may be developed in the pre-thin film 110 and crystallinity (regularity of crystal) of the pre-thin film 110 is non-uniform. When the crystallinity is non-uniform, a dipole moment (disproportion of charge) is larger. As a result, the dipole moment of the pre-thin film 110 is larger than the dipole moment of the un-implanted layer (i.e., the lower pre-electrode 109). As the dipole moment of the layer becomes larger, the microwave becomes absorbed more extensively. Thus, an absorption rate of the lower pre-electrode 109 is lower than the absorption rate of the pre-thin film 110, and the pre-thin film 110 is heated more extensively than the lower pre-electrode 109. As a result, temperature of the pre-thin film 110 becomes higher than temperatures of other layers (e.g., the lower pre-electrode 109).

The microwave is preferably applied in a chamber containing oxygen gas when oxygen lacks in the pre-thin film 110, because annealing effect of the pre-thin film 110 is higher. The microwave may be applied in a chamber containing nitrogen gas, when the pre-thin film includes nitride. A pressure in the chamber is preferably set as same as atmosphere pressure, because an unintended ignition can be suppressed.

A power of applying the microwave is, for example, equal to or greater than 1 kW and equal to or smaller than 6 kW. When the power is greater than 6 kW, the temperature of the pre-thin film 110 may increase rapidly and the pre-thin film 110 may thermally expand and be broken.

A time period of applying the microwave may be, for example, equal to or longer than five minutes and equal to or shorter than 30 minutes. If the time period is shorter than five minutes, the pre-thin film 110 may not be heated enough. If the time period is longer than 30 minutes, the pre-thin film 110 may be heated excessively, the pre-thin film 110 may be broken, and an electrical characteristic of the pre-thin film 110 may be deteriorated.

An area and depth of the area in which the microwave is applied are able to be adjusted. The applied area has a wide which is, for example, equal to or wider than 1 nm and equal to or narrower than 9 nm.

As described above, the defect of the pre-thin film 110a is annealed through the microwave.

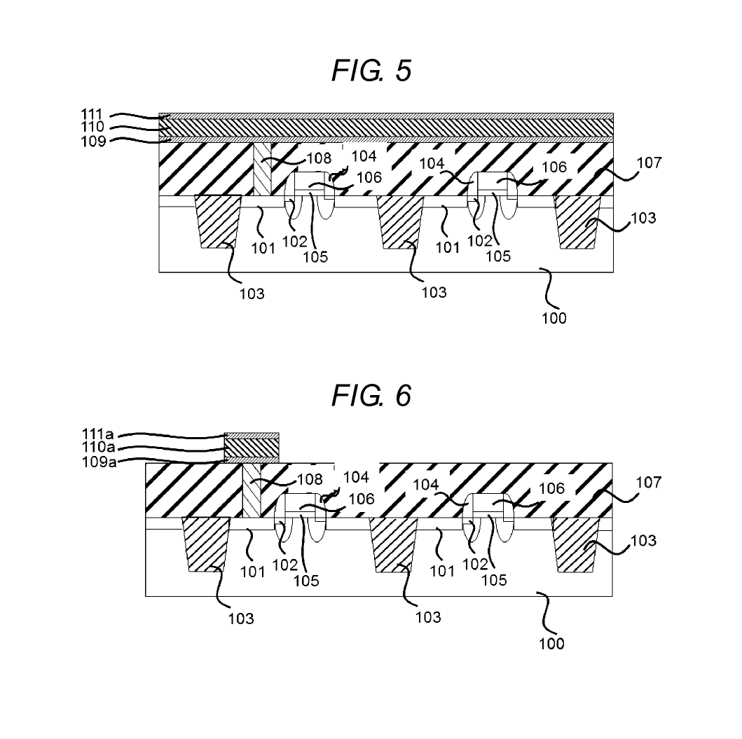

As illustrated in FIG. 5, an upper pre-electrode 111 is formed above the pre-thin film 110. Then, a photo resist pattern (not shown) is provided on the upper pre-electrode 111. Then, as illustrated in FIG. 6, the lower pre-electrode 109, the pre-thin film 110, and the upper pre-electrode 111 are etched and patterned. A lower electrode 109a, a thin film 110a, and an upper electrode 111 are formed through this etching. The lower electrode 109a, the thin film 110a, and the upper electrode 111 work as a capacitor.

In this embodiment, the ion may be implanted after providing pre-thin film 110, and the microwave may be applied after the upper pre-electrode 111 is formed. The microwave may be applied after the ion is implanted and the lower pre-electrode 109, the pre-thin film 110, and the upper pre-electrode 111 are etched because the area corresponding to the thin film 110a can be selectively heated using the microwave.

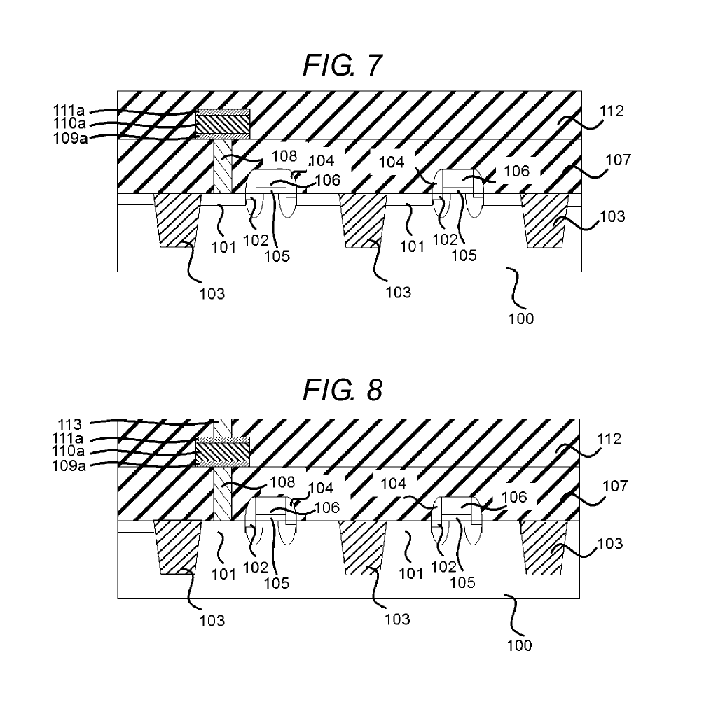

As illustrated in FIG. 7, a second insulating layer 112 is formed on the first insulating layer 107. The second insulating layer 112 is formed using a CVD method or a spattering method. As the second insulating layer 112, it is possible to use, for example, a silicon oxide (SiO2) or a silicon nitride (Si3N4).

As illustrated in FIG. 8, a via is formed in the second insulating layer 112 and the upper electrode 111a is exposed. Then, a second tungsten plug 113 is formed on the upper electrode 111a filling the via.

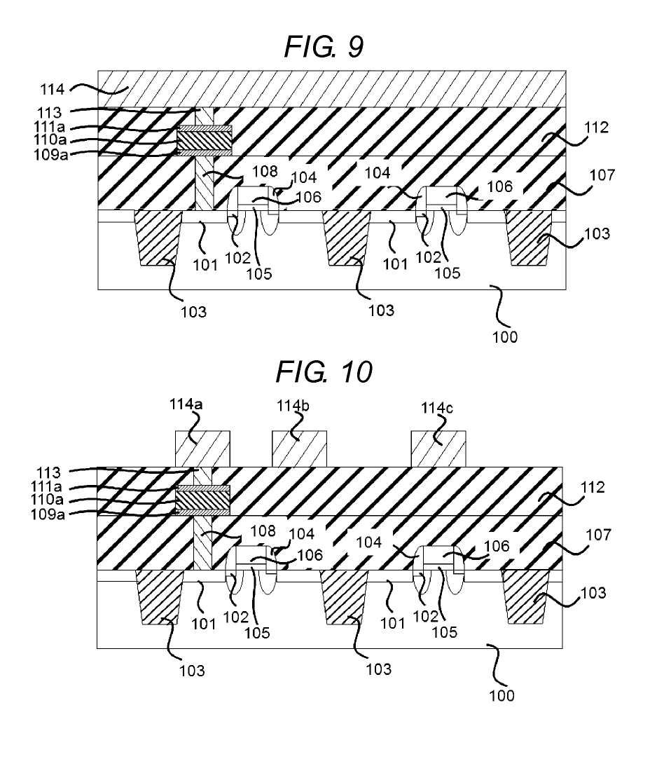

As illustrated in FIG. 9, a first pre-metal wiring layer 114 is formed above the second tungsten plug 113 and the second insulating layer 112.

Then, a photo resist pattern (not shown) is provided on the first pre-metal wiring layer 114. Then, as illustrated in FIG. 10, the first pre-metal wiring layer 114 is etched and patterned. First metal wirings 114a, 114b, and 114c are formed through this etching.

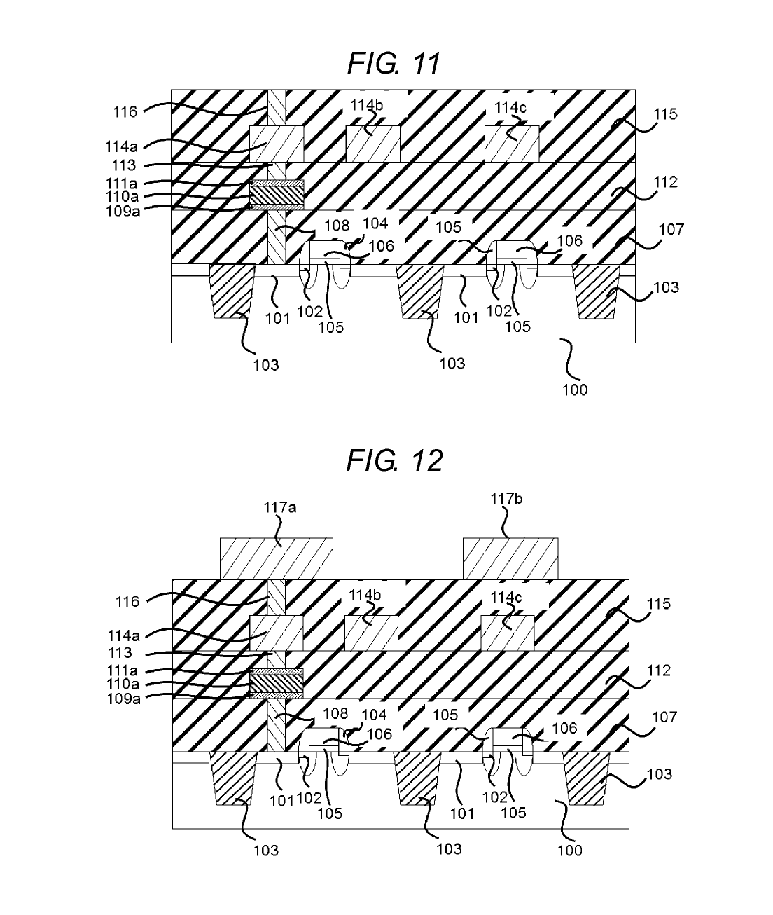

As illustrated in FIG. 11, a third insulating layer 115 is formed above the first metal wirings 114a, 114b, 114c and the second insulating layer 112. The first metal wiring is electrically connected to the second tungsten plug 113. Then, the via is formed in the third insulating layer 115 and the first metal wiring 114a is exposed. Then, a third tungsten plug 116 is provided on the first metal wiring 114a filling the via after the third insulating layer 115 is formed.

Then, a second pre-metal wiring layer is formed above the third insulating layer 115, and the photo resist pattern (not shown) is provided on the second pre-metal wiring layer. Then, as illustrated in FIG. 12, the second pre-metal wiring layer is etched and patterned. Second metal wirings 117a and 117b are formed through this etching.

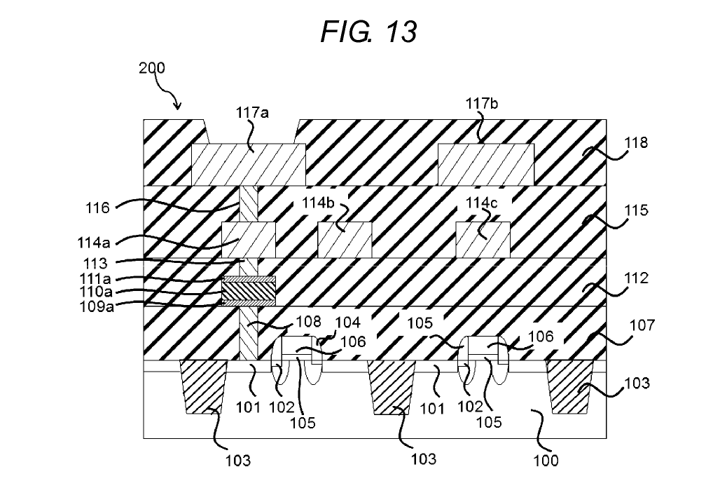

As illustrated in FIG. 13, a forth insulating layer 118 is provided on the third insulating layer 115. As a result, the semiconductor device 200 is manufactured.

The semiconductor device 200, according to the present embodiment, has a striking effect. the manufacturing method according to the present embodiment includes a step of implanting the oxygen or nitrogen ion in the pre-thin film. 110 and a step of selectively annealing at least a part of the pre-thin film 110 by applying the microwave after the implantation is carried out, which causes the absorption rate of the pre-thin film 110 to be increased. It is possible to suppress annealing from being carried out on an unintended portion. Moreover, it is possible to suppress the crystal defect and to provide the thin film 110a having the aimed composition.

The area corresponding to the thin film 110a is selectively heated through the microwave. As temperature increase of the other layers may be suppressed, temperature increase of the entire semiconductor device 200 may be suppressed. As a result, it is possible to suppress oxidization of the upper electrode 111a and the lower electrode 109a caused by oxygen in the thin film 110a as dielectric layer.

Here, it is assumed that the entire semiconductor device 200 is heated to anneal the crystal defect that is caused by the ion implantation. In this case, the metal atom in layers adjacent to the thin film 110a may be diffused into the thin film 110, or the thin film 110a may be oxidized. Further, a layer may be produced through a reaction at a boundary, for example, between the upper electrode 111a and thin film 110a or between the lower electrode 109a and the thin film 110a. Such a reaction may occur at a boundary between the upper electrode 111a and thin film 110a, between the lower electrode 109a and the thin film 110a, between the first tungsten plug 108 and the lower electrode 109a, between the second tungsten plug 113 and the upper electrode 111a, between the first insulating layer 107 and the second insulating layer 112, between the first metal wiring 114a and the second tungsten plug 113, between the first metal wiring 114a and the third tungsten plug 116, or the like. When the diffusion or oxidization occurs, the thin film 110a may not have the aimed composition, and as a result electrical characteristic of the thin film 110a may be deteriorated. Further, when a semiconductor device including the thin film 110a operates, the layer produced by the reaction at the boundaries may cause leaking a current or trapping an electron.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
forming a first layer above a semiconductor substrate;
implanting in a surface of the first layer, at least one kind of ions of an element contained in the first layer; and
applying microwave to the first layer in which said at least one kind of the ions are implanted.

2. The method according to claim 1, wherein the ions include oxygen ions or nitrogen ions.

3. The method according to claim 1, wherein the microwave is applied to heat process defects in the first layer produced by implanting the ions.

4. The method according to claim 1, wherein the first layer is an insulating layer.

5. The method according to claim 1, further comprising:
forming a second layer above the first layer,
wherein the ions is implanted before the second layer is formed, and the microwave is applied after the second layer is formed.

6. The method according to claim 5, wherein
the first layer absorbs the microwave better than the semiconductor substrate.

7. The method according to claim 1, further comprising:
forming a first conductive layer above the semiconductor substrate; and
forming a second conductive layer on the first layer,
wherein the first layer is an insulating layer and formed on the first conductive layer.

8. The method according to claim 7, further comprising:
patterning the first conductive layer, the first layer, and the second conductive layer, into a shape of a capacitor.

9. The method according to claim 7, wherein
the semiconductor substrate includes a substrate and an insulating layer formed on the substrate, a plurality of transistors being formed within the substrate and the insulation layer, and the first conductive layer is formed on the insulating layer of the semiconductor substrate.

10. A method for manufacturing a capacitor for a semiconductor device, comprising:
forming a first conductive layer;
forming an insulating layer on the first conductive layer;
implanting in a surface of the insulating layer, at least one kind of ions of an element contained in the insulating layer;
forming a second conductive layer on the insulating layer;
patterning the first conductive layer, the insulating layer, and the second conductive layer; and
applying microwave to the insulating layer in which said at least one kind of the ions are implanted.

11. The method according to claim 10, wherein the ions include oxygen ions or nitrogen ions.

12. The method according to claim 10, wherein the microwave is applied such that defects produced in the insulating layer by implanting the ions are heat-processed.

13. The method according to claim 10, wherein the microwave is applied after the second conductive layer is formed.

14. The method according to claim 13, the insulating layer absorbs the microwave better than the first and second conductive layers.

15. The method according to claim 10, wherein the microwave is applied after the patterning is carried out.
